(19) United States
(12) Patent Application Publication
(10) Pub. No.: US 2005/0184372 A1
(43) Pub. Date: Aug. 25, 2005

(54) Three-dimensional mounting structure and method for producing the same

(75) Inventors: Toshiyuki Asahi, Hirakata-shi (JP); Seiichi Nakatani, Hirakata-shi (JP); Tousaku Nishiyama, Nara-shi (JP); Kiyoshi Nakanishi, Kawasaki-shi (JP); Ken Muramatsu, Yokohama-shi (JP)

Correspondence Address: MERCHANT & GOULD PC, P.O. BOX 2903, MINNEAPOLIS, MN, 55402-0903, US

(73) Assignee: Matsushita Electric Industrial Co., Ltd., Kadoma-shi (JP)

(21) Appl. No.: 11/059,845

(22) Filed: Feb. 16, 2005

(30) Foreign Application Priority Data
Feb. 20, 2004 (JP) 2004-044263

(51) Int. Cl. H01L 23/48

(52) U.S. Cl. 257/678

(57) ABSTRACT

A three-dimensional mounting structure according to the present invention includes: a first main wiring board having a first wiring pattern on its surface and an electronic component mounted on the wiring pattern; a second main wiring board disposed facing the first main wiring board and having a second wiring pattern on its surface; and a lead frame connector disposed substantially perpendicular to the first main wiring board and the second main wiring board at an end portion of the two wiring bards, wherein the lead frame connector includes a plurality of lead wires made of an electrically conductive material and a resin portion to which the plurality of lead wires are fixed, wherein an end portion of each of the plurality of lead wires is exposed from the resin portion, and wherein at least two of the plurality of lead wires are each electrically connected to both the first wiring pattern of the first main wiring board and the second wiring pattern of the second main wiring board. Thus, there is provided a three-dimensional mounting structure that can realize high-density, multi-function mounting, allows easy testing, as well as repair and exchange of various elements and can reduce the mounting area, and a method for producing such a three-dimensional mounting structure.

### BACKGROUND OF THE INVENTION

1. Field of the Invention

The present invention relates to three-dimensional mounting structures that are useful for, for example, mobile phones, and to methods for producing the same. In particular, the invention relates to a three-dimensional mounting structure that can realize high-density, multi-function mounting, and to a method for producing such a three-dimensional mounting structure.

2. Related Background Art

With the recent miniaturization and performance enhancement of electronic devices, there is an increasing demand for the high-density mounting of electronic components mounted on printed boards and the performance enhancement of circuit boards on which the electronic components are mounted. Under such circumstances, extensive research and development have been conducted on, for example, system-on-chip (SOC) technology that realizes high-density, multi-function mounting with the use of system LSIs in which a one-chip semiconductor device is provided with many functions, and system-in-package (SIP) technology that realizes high-density, multi-function mounting by constituting one package with at least one semiconductor chip and a plurality of active components, passive components and the like.

Furthermore, attention is being shifted from commonly used two-dimensional mounting that provides a flat configuration to three-dimensional mounting by which components are mounted in a stacked configuration, in order to realize high-density, multi-function mounting. Examples of the three-dimensional mounting include those using three-dimensional packages (e.g., stacked CSPs) in which bare chips are stacked and those using three-dimensional modules of stacked packages in which a single independent package of a semiconductor chip is formed and a plurality of such packages are stacked to form a three-dimensional configuration. Furthermore, there also are techniques of realizing high-density, multi-function mounting by stacking wiring boards on which electronic components (e.g., semiconductor chips and passive components) are mounted. These techniques are disclosed in, for example, JP 2000-31617A, JP H8-264918A, JP H6-111869A, JP H5-218613A and JP H4-366567A.

With the SOC technology, all or most of the necessary components in an electronic system are mounted on a one-chip semiconductor device, so that it is possible to perform a so-called “ultimate” high-density, multi-function mounting. On the other hand, there also is a significant disadvantage in terms of the cost or the time required for designing and development. That is, all the necessary components may not need to be formed as a semiconductor integrated circuit, and moreover, if designing and development are carried out every time the version of a product is upgraded, an increase of the development cost and a delay of delivery of the product tend to occur. In addition, it may not be necessary to mount all the components on the product due to cost reasons. On the other hand, SIP technology can use devices that are completed independently, and therefore is significantly advantageous in terms of the cost or the time required for designing and development, although it requires a somewhat larger mounting area than SOC technology.

The use of the stacked CSPs or the three-dimensional modules of stacked packages enables a relatively large miniaturization of the mounting area for components of the same kind (e.g., memories), thus making it possible to achieve high density. However, in order to apply these techniques to the entire system, the same problems as those encountered in the SIP technology may occur. The technique using a multilayer configuration of wiring boards on which electronic components are mounted still has the potential that design and development can be carried out taking into consideration the whole of a system. With the techniques suggested in the above-described patent references, it is possible to increase the mounting area by using through holes or connectors (connection terminals) to provide connections between the wiring boards.

However, it is more difficult to produce a multilayer configuration of wiring boards on which electronic components are mounted (as in the configurations disclosed in the above-described patent references) than commonly used wiring boards (printed circuit boards) on which electronic components are mounted two-dimensionally, thus increasing the manufacturing cost. This is not considered a significant problem in these days, because the advantage of ensuring an increase of the mounting area is given priority. Nevertheless, this is problematic in terms of the manufacturing cost and the throughput. Furthermore, among the techniques disclosed in the above-described patent references, in the case of the technique of using through holes to provide connections between the wiring boards, the wiring boards only can be tested in the stacked state, presenting the problem that defects cannot be repaired after the product has been completed. On the other hand, in the case of using a connector to provide connection, repair and exchange are possible, but the connector and its mounting space consume a large space. Therefore, considering the disadvantage caused by an increased mounting area, no significant effect can be achieved. Moreover, the techniques disclosed in the above-described patent references are not described taking into consideration of the entire system, and the members that provide connections between the wiring boards have a mere function of providing electrical connection. In this respect, these techniques still have room for improvement.

### SUMMARY OF THE INVENTION

In order to solve the above-described problems, the present invention provides a three-dimensional mounting structure that can realize high-density, multi-function mounting, can facilitate testing, as well as repair and exchange of various elements, and can reduce the mounting area, and a method for producing the same.

A three-dimensional mounting structure according to the present invention includes:

a first main wiring board having a first wiring pattern on its surface and an electronic component mounted on the wiring pattern;

a second main wiring board disposed facing the first main wiring board and having a second wiring pattern on its surface; and

a lead frame connector disposed substantially perpendicular to the first main wiring board and the second main wiring board at an end portion of the two wiring bards,

wherein the lead frame connector comprises a plurality of lead wires made of an electrically conductive material and a resin portion to which the plurality of lead wires are fixed,

wherein an end portion of each of the plurality of lead wires is exposed from the resin portion, and

wherein at least two of the plurality of lead wires are each electrically connected to both the first wiring pattern of the first main wiring board and the second wiring pattern of the second main wiring board.

A method for producing a three-dimensional mounting structure according to the present invention includes:

arranging, side by side, a first main wiring board having a wiring pattern on its surface and an electronic component mounted on the wiring pattern, and a second main wiring board having a wiring pattern on its surface;

electrically connecting, to the wiring pattern of the first main wiring board, one end of each of a plurality of lead wires of a lead frame connector comprising the plurality of lead wires and a resin portion to which the lead wires are fixed, and electrically connecting the other end of each of the lead wires to the wiring pattern of the second main wiring board; and

bending the lead wires of the lead frame connector in such a manner that the first main wiring board and the second main wiring board face each other.

Another method for producing a three-dimensional mounting structure according to the present invention includes:

providing a multi-board substrate including a plurality of combinations of a first main wiring board having a wiring pattern on its surface and a second main wiring board disposed adjacent to the first main wiring board and having a wiring pattern on its surface;

mounting an electronic component on each of the wiring pattern of the first main wiring board and the wiring pattern of the second main wiring board in the multi-board substrate;

electrically connecting one end and the other end of each of a plurality of lead wires of a lead frame connector comprising the plurality of lead wires and a resin portion to which the lead wires are fixed, respectively, to the wiring pattern of the first main wiring board and the wiring pattern of the second main wiring board in the combinations included in the multi-board substrate;

removing, from the multi-board substrate, the combinations of the first main wiring board and the second main wiring board connected via the lead frame connector; and

bending the lead wires of the lead frame connector in such a manner that the first main wiring board and the second main wiring board face each other.

### BRIEF DESCRIPTION OF THE DRAWINGS

FIGS. 1A and 1B are cross-sectional views schematically showing the configuration of a three-dimensional mounting structure used as a reference of the present invention.

FIG. 2 is a cross-sectional view schematically showing a configuration of a three-dimensional mounting structure according to Embodiment 1 of the present invention.

FIG. 3 is a cross-sectional view schematically showing a configuration of the three-dimensional mounting structure according to Embodiment 1 of the present invention.

FIGS. 4A to 4C are diagrams for illustrating the steps of a method for producing a lead frame connector according to Embodiment 1 of the present invention.

FIGS. 5A and 5B are cross-sectional views for illustrating the steps of a method for producing the three-dimensional mounting structure according to Embodiment 1 of the present invention.

FIG. 6 is a cross-sectional view schematically showing a configuration of the three-dimensional mounting structure according to Embodiment 1 of the present invention.

FIG. 7 is a cross-sectional view schematically showing a configuration of another three-dimensional mounting structure according to Embodiment 1 of the present invention.

FIG. 8 is a top view showing a multi-board substrate for illustrating a method for producing the three-dimensional mounting structure according to Embodiment 1 of the present invention.

FIG. 9 is a top view showing the same substrate in the mounted state.

FIG. 10 is a top view showing the multi-board substrate shown in FIG. 9 from which a set of boards has been cut out.

FIG. 11A is a top view for illustrating a method for producing the three-dimensional mounting structure according to Embodiment 1 of the present invention, and FIG. 11B is a cross-sectional view thereof.

FIG. 12 is a top view of the lead frame portion of a lead frame connector for the three-dimensional mounting structure according to Embodiment 1 of the present invention.

FIG. 13 is a top view of the same lead frame portion on which components are mounted on the lead frame.

FIG. 14 is a top view of the same lead frame portion for illustrating the step of a method for producing a component-incorporating lead frame connector on which the components are mounted and molded with resin.

FIG. 15A is a top view of the same component-incorporating lead frame connector, and FIG. 15B is a side view thereof.

FIG. 16 is a perspective view schematically showing a configuration of a lead frame connector according to Embodiment 2 of the present invention.

FIG. 17 is a cross-sectional view schematically showing a configuration of a three-dimensional mounting structure according to Embodiment 2 of the present invention.

FIG. 18A is a cross-sectional view schematically showing a configuration of the three-dimensional mounting structure according to Embodiment 2 of the present invention, and FIG. 18B is a top view thereof.

FIG. 19 is a cross-sectional view schematically showing a configuration of the three-dimensional mounting structure according to Embodiment 2 of the present invention.

FIG. 20 is a cross-sectional view schematically showing a configuration of another three-dimensional mounting structure according to Embodiment 2 of the present invention.

FIG. 21A is a cross-sectional view showing a connector for the another three-dimensional mounting structure according to Embodiment 3 of the present invention, and FIG. 21B is a cross-sectional view of the same three-dimensional mounting structure.

### DETAILED DESCRIPTION OF THE INVENTION

The present invention provides a three-dimensional mounting structure electrically connected to a first main wiring board and a second wiring board at least at their end portions with a lead frame connector. Here, “three-dimensional mounting structure” refers to a structure in which at least two wiring boards are stacked, with an electronic component mounted on one side of each of the stacked wiring boards.

In the present invention, “mounting structure” refers to a structure on which at least one electronic component is mounted on a structure (e.g., a board) provided with conductors.

“Wiring” transmits an electric signal, and usually is made of metal.

“Electronic component” is a generic term for active components (e.g., a semiconductor device and a semiconductor package) and passive components (e.g., a resistor, coils, a capacitor and a surface acoustic wave (SAW) filter).

“Chip component” refers to chip-shaped passive components such as resistors, coils and capacitors.

“Semiconductor device” refers to an unpackaged semiconductor. In the case of bare chip mounting, the semiconductor device is mounted on a board.

“Lead frame connector” is, e.g., a connector using a lead frame that has been used as internal wiring of a semiconductor package by etching or press-forming a thin metal plate. The lead frame connector can be used to make a connection between substrates or the like.

In the present invention, it is preferable that at least two lead wires of the lead frame connector each have a bent portion. The reason is that this is convenient for folding the first main wiring board and the second main wiring board at the end portions of the two boards.

It is preferable that the electronic components mounted on the first main wiring board and the second main wiring board are disposed on the inner side of each of the two wiring boards. The electronic component is protected by the two wiring boards.

It is preferable that the resin portion of the lead frame connector contains a further electronic component. Examples of the electronic component include an anti-noise component. Although noise tends to be generated by static electricity and the like, the generation of noise can be prevented by disposing an anti-noise component inside the connector. Examples of the anti-noise component include a by-pass capacitor, a decoupling capacitor, a delay inductor, a resistor and a varistor. One of these may be used alone, or more than one of them may be used in combination. Of them, the varistor particularly is preferable.

In the present invention, it is preferable that the electronic component mounted on the main wiring boards is at least one selected from a semiconductor device and a chip component.

It is preferable that one end of each of the at lest two lead wires of the lead frame connector is connected to the wiring pattern of the first main wiring board with solder, and the other end of each of the at least two lead wires is connected to the wiring pattern of the second main wiring board with solder. This is because solder provides high mechanical strength.

A side board that is folded to a lateral side of at least one of the first main wiring board and the second main wiring board further may be provided. The lead frame connector further may include a plurality of side lead wires disposed in a direction perpendicular to the plurality of lead wires connected to each of wiring of the first main wiring board and the second main wiring board, and the side lead wires may be electrically connected to the wiring of the side board. In this case, it is possible to connect a maximum of four boards with a single connector.

A third wiring board or an electromagnetic wave-shielding member that is folded, and a further lead frame connector including a plurality of lead wires made of an electrically conductive material and a resin portion to which the plurality of lead wires are fixed further may be provided, and the third wiring board or the electromagnetic wave-shielding member may be connected, via the further lead frame connector, to an end of at least one of the first main wiring board and the second main wiring board that is opposite of an end at which the two wiring boards are connected. In this case, it is possible to form a mounting structure of three or more folded layers. Furthermore, in the case of inserting an electromagnetic wave-shielding member between the first and the second main wiring boards, it is possible to shield electromagnetic waves between the two boards.

A substantially closed space may be formed by the first main wiring board, the second main wiring board and the electromagnetic wave-shielding member.

Furthermore, at least one of the first main wiring board and the second main wiring board may be an electronic component-incorporating board that contains an electronic component in its substrate. Embedding an electronic component in the board increases the mechanical strength, improving the handleability.

It is preferable that at least one of a perforation and a V-shaped cut is formed on the periphery of the first main wiring board and the second main wiring board in the multi-board substrate. This is for facilitating separation of the two wiring boards.

It is preferable that the step of mounting an electronic component on each of the first main wiring board and the second main wiring board and the step of electrically connecting one end and the other end of each of the lead wires of the lead frame connector, respectively, to the wiring pattern of the first main wiring board and the wiring pattern of the second main wiring board are performed in the same step. In the mounting and connecting steps, e.g., cream solder is applied, and then reflowing is performed to establish the electrical connections simultaneously. Therefore, when the mounting step and the connecting step are performed separately, the solder of the wiring boards on which the electronic components were first mounted is remelted, so that the electronic component or the lead frame connector may be detached therefrom. Moreover, the repetition of thermal hysteresis can cause damage to the components mounted on the wiring boards.

In a production method according to the present invention, it is preferable that the lead frame connector is formed by arranging a plurality of lead wires and thereafter forming a resin portion at a central area of the plurality of lead wires by transfer molding.

Furthermore, the plurality of lead wires may be arranged in a lead frame including the lead wires, and an electronic component may be placed on a portion of the central area of the plurality of lead wires, with the electronic component sealed in the resin by the transfer molding. Here, the electronic component refers to an anti-noise component.

In yet another three-dimensional mounting structure according to the present invention, a portion of the at least two of the lead wires of the lead frame connector that is exposed from the resin is curved, and the first main wiring board is provided with a connector electrically connected to the wiring pattern of this first main wiring board and capable of housing the curved areas of the lead wires of the lead frame connector. The second main wiring board also is provided with a connector electrically connected to the wiring pattern of this second main wiring board and capable of housing the curved areas of the lead wires of the lead frame connector. The curved areas of the lead wires of the lead frame connector are inserted into the connectors.

The above-described connectors have a configuration in which the curved areas of the lead wires can be housed and removed. Then, the wiring pattern of the first main wiring board and the wiring pattern of the second main wiring board are electrically connected with at least two lead frame connectors described above.

A method for producing this three-dimensional mounting structure provides a lead frame connector including a plurality of lead wires and a resin portion to which the plurality of lead wires are fixed, with a portion of the lead wires that is exposed from the resin portion being curved. Next, the method arranges two main wiring boards, each of which has a wiring pattern on its surface and is provided with a connector electrically connected to the wiring pattern and capable of housing the curved areas of the lead wires of the lead frame connector in such a manner that the sides of the wiring boards on which the connectors are provided face each other. Next, the method disposes the lead frame connector between the connectors, and thereafter inserts the curved areas of the lead wires of the lead frame connector into the connectors.

The lead frame connector may be produced by arranging a plurality of lead wires, then forming a resin portion at a central area of the plurality of lead wires by transfer molding, and then causing the area of the lead wires that is exposed from the resin portion to curve.

The plurality of lead wires may be arranged in a lead frame including the plurality of lead wires, and an electronic component may be placed on a portion of a central area of the plurality of lead wires, with the electronic component sealed in the resin by the transfer molding.

The three-dimensional mounting structure according to the present invention is suitable for a portable electronic device. This portable electronic device is provided with the above-described three-dimensional mounting structure and a casing for housing the three-dimensional mounting structure.

With the present invention, a three-dimensional mounting structure is produced by electrically connecting one end and the other end of each of the lead wires of the lead frame connector, respectively, to the wiring pattern of the first main wiring board and the wiring pattern of the second main wiring board, and thereafter bending the lead wires of the lead frame connector in such a manner that the first main wiring board and the second main wiring board are disposed substantially parallel to each other. Accordingly, it is possible to produce a three-dimensional mounting more easily than using conventional methods for producing a three-dimensional mounting structure. Furthermore, with the present invention, the first main wiring board and the second main wiring board are electrically connected with the lead frame connector, testing, as well as repair and exchange of various elements (the first main wiring board, the second main wiring board and the lead frame connector) constituting the three-dimensional mounting structure can be performed easily. Moreover, it is possible to obtain a three-dimensional mounting structure for which there is no limitation on the mounting area. Furthermore, since an electronic component can be incorporated in the lead frame connector, it is possible to increase the mounting area even further.

It is possible to incorporate an electronic component (e.g., an anti-noise component) in the lead frame connector. When the anti-noise component is mounted on the lead frame connector, it is possible to form a noise-resistant module (three-dimensional mounting structure), while utilizing the mounting areas of the first main wiring board and the second main wiring board more effectively than when the anti-noise component is provided on the first main wiring board and the second main wiring board. In addition, it is possible to increase the design flexibility of the first main wiring board and the second main wiring board.

Furthermore, since one end and the other end of the lead wires of the lead frame connector are utilized, stress or distortion exerted on the three-dimensional mounting structure can be absorbed or alleviated with the lead wires of the lead frame connector. Consequently, it is possible to realize a three-dimensional mounting structure having a great reliability against, for example, impact in the event of a fall.

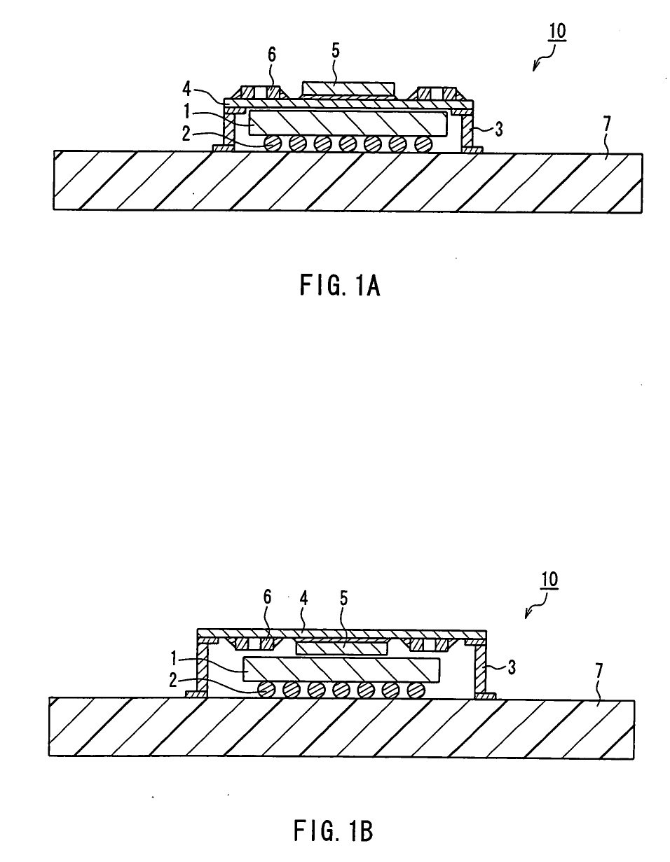

To develop a three-dimensional mounting structure that can realize high-density, multi-function mounting, the inventors first made a study on a three-dimensional mounting structure 10 having the configuration shown in FIGS. 1A and 1B. FIGS. 1A and 1B are reference drawings of the present invention.

In the three-dimensional mounting structure 10 shown in FIG. 1A, a CSP (Chip Size Package) semiconductor device 1 is mounted on a mother board 7, and a wiring board 4 is disposed above the semiconductor chip 1. The CSP 1 is connected to the mother board 7 via solder balls 2. The wiring board 4 is supported by a connection terminal 3, and connected to the mother board 7 by the connection terminal 3. A bare chip semiconductor device 5 and chip components 6 are mounted on the upper surface of the wiring board 4. On the other hand, a three-dimensional mounting structure 10 shown in FIG. 1B has substantially the same configuration as that shown in FIG. 1A, and only differs in that the bare chip semiconductor device 5 and the chip components 6 are mounted on the lower surface of the wiring board 4.

In both of the three-dimensional mounting structures 10 shown in FIGS. 1A and 1B, the components 5 and 6 can be disposed in an area above the CSP 1. Accordingly, it is possible to increase the mounting area, and to allow a plurality of components to be mounted, thus realizing high-density mounting and multi-function mounting with relative ease.

Although there is no particular problem with the three-dimensional mounting structures 10 shown in FIGS. 1A and 1B at the current level of the technology, the inventors carried out a further study based on the following assumption.

In the field of mobile phones, the pace at which models are changed is fast, so that manufacturers are required to produce the next models with a short designing period and a short development period. Ordinarily, once it has been decided that a new model is introduced, a circuit board for realizing various systems or circuits is designed and developed in accordance with the functions and the configuration of the new model, and the circuit board is produced accordingly. In the case of mobile phones, the mounting area is limited extremely, as compared with other electronic devices (or other portable electronic devices). For this reason, even a minor change often requires designing the circuit board from the beginning, in order to dispose the circuit board in the case of a mobile phone appropriately. Accordingly, even if the three-dimensional mounting structures 10 shown in FIGS. 1A and 1B are appropriate for certain models, they often have to be changed for the next models, even though their structures and arrangements may be appropriate for the current models.

On the other hand, from the viewpoint of the functions and the circuits of a mobile phone, there are parts that need to be adapted to a new model, and parts for which the functions and the circuits of the current model can be used as they are. That is, each time a mobile phone is provided with various additional functions such as camera functionality, television functionality and Internet functionality, circuits for the additional functions need to be incorporated in the mobile phone, although its basic circuit does not change significantly. Viewed in this light, it is possible to provide a great advantage in circuit design by developing a three-dimensional mounting structure having a structure that does not require configuring the circuit board from the beginning in accordance with the limitation to the mounting area, or a structure that does not require a significant change of the circuit board for a minor change. For the conventional three-dimensional mounting structures, there has been a lack of such a consideration, and a structure that merely allows effective utilization of the mounting area has been proposed thus far.

Under the above-described considerations, the inventors have conceived the idea of providing a three-dimensional mounting structure that does not require a significant change in the design of the circuit board (e.g., designing the circuit board from the beginning) for a minor change made at the time of changing models, unlike the conventional three-dimensional mounting structures. This makes it possible to achieve a great advantage in mobile phone applications, in which the pace at which models are changed is fast and the next models need to be produced with short designing and development periods.

The purpose or idea of modularization originally lies in allowing various functions of circuit blocks to be shared by integrating the functions of the circuit blocks to be exerted as a complete function. The inventors also noted this original purpose. This makes it possible to standardize a module used for electronic devices and to facilitate model upgrades, provision of additional functions and the like, thus realizing a shorter development period and a reduced development cost. The modularization of functions also can provide the effects of decreasing the number of electronic connection terminals between modules and permitting the use of a low-cost board for a mother board on which modules are mounted. Furthermore, it is possible to simplify noise protection for electronic device sets by integrating the functions and providing noise protection for each module. This also makes it possible to shorten the development period for electronic devices, for which higher speed and higher frequency are being achieved in recent years. Therefore, it is preferable that a three-dimensional mounting structure, which can be called an advanced form of a module, also achieves the above-described effects. Also in the case of a three-dimensional mounting structure, to what extent functions can be integrated, i.e., whether any kinds of components can be mounted and whether noise protection can be provided, can be an important factor.

In the configurations shown in FIGS. 1A and 1B, the CSP 1 and the wiring board 4 disposed thereabove cannot be electrically connected directly. Therefore, they are electrically connected via the mother board 7. As described above, from the viewpoint of integrating functions that is the original idea behind modularization, the configurations shown in FIGS. 1A and 1B cannot be called effective modules. That is, these configurations are obtained simply by forming two layers of components that are not related to one another as circuits, and achieve little effect in reducing the cost of mother boards.

As a result of a further study on the configurations shown in FIGS. 1A and 1B in view of the above-described considerations, the inventors have conceived that, although the connection terminal 3 functions appropriately in the context of these configurations function, a novel three-dimensional mounting structure can be realized by introducing new ideas in the connection terminal 3 instead of being bound by the conventional technology, thus achieving the present invention.

Hereinafter, embodiments of the present invention are described with reference to the accompanying drawings. For the sake of simplicity, components having substantially the same functions are denoted by the same reference numerals in the drawings. It should be noted that the present invention is not limited to the following embodiments.

### Embodiment 1

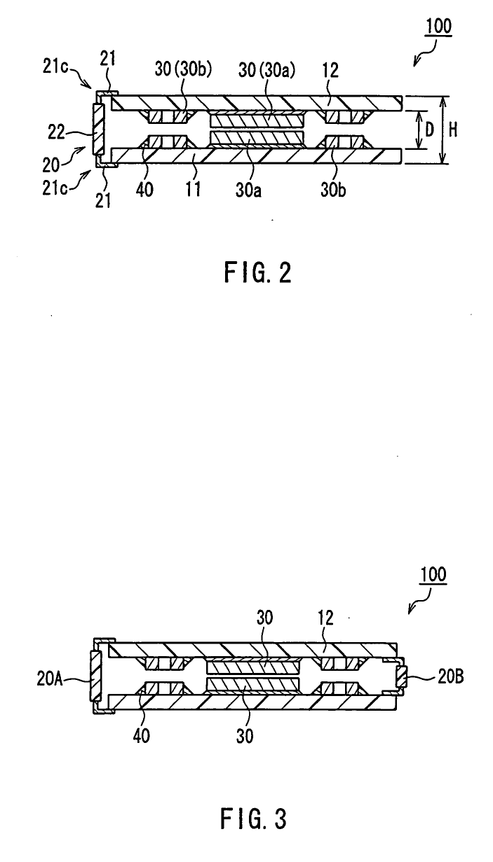

A three-dimensional mounting structure 100 according to Embodiment 1 of the present invention is described with reference to FIG. 2.

The three-dimensional mounting structure 100 shown in FIG. 2 includes: a first main wiring board 11; a second main wiring board 12 disposed substantially parallel to the first main wiring board 11; and a lead frame connector 20 disposed substantially perpendicular to the first main wiring board 11 and the second main wiring board 12. The first main wiring board 11 has a wiring pattern (not shown) on its surface, and electronic components 30 (30a, 30b) are mounted on the wiring pattern. Similarly to the first main wiring board 11, the second main wiring board 12 also has a wiring pattern (not shown) on its surface, and the electronic components 30 (30a, 30b) are mounted also on the wiring pattern of the second main wiring board 12. Examples of the electronic components 30 include a semiconductor device (e.g., a CSP and a bare chip) 30a and a chip component (e.g., a chip inductor, a chip capacitor and a chip resistor) 30b. In this embodiment, the electronic components 30 are mounted on the first main wiring board 11 or the second main wiring board 12 with solder 40.

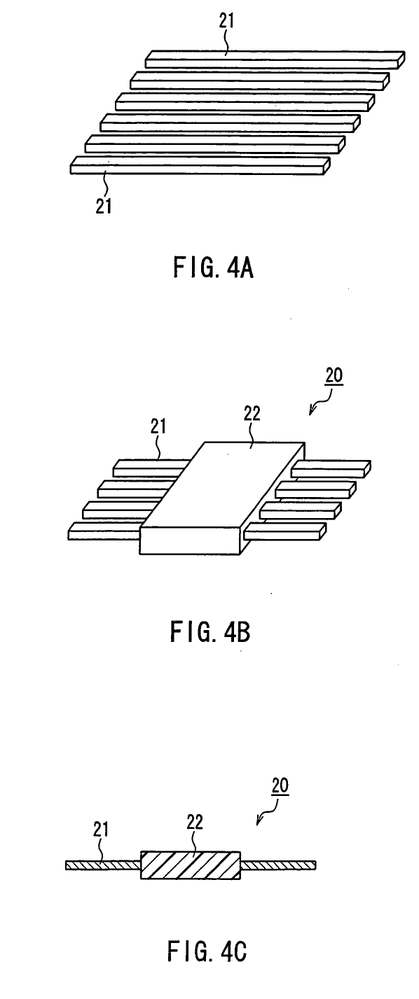

The lead frame connector 20 includes a plurality of lead wires 21 and a resin portion 22 to which the plurality of lead wires 21 are fixed. The ends of the lead wires 21 are exposed from the resin portion 22, and the lead wires 21 are electrically connected to both the wiring pattern of the first main wiring board 11 and the wiring pattern of the second main wiring board 12. Accordingly, the first main wiring board 11 and the second main wiring board 12 are electrically connected via the lead frame connector 20. An overall configuration (in a perspective view) of the lead frame connector 20 is shown in FIG. 4B. In FIGS. 4A to 4C, the lead wires 21 are made of an electrically conductive material, for example, metal such as copper. The number of the lead wires 21 are at least two, but there is no particular limitation on its upper limit (four, in FIG. 4B), and may be determined appropriately in accordance, for example, with the wiring pattern of the first main wiring board 11 or the second main wiring board 12. In this embodiment, the resin portion 22 is made of an epoxy resin (e.g., an epoxy resin for transfer molding).

The lead frame connector 20 may have the function of a wiring pattern, for example, by providing connections between different lead wires in the resin portion 22 or at the lead wire 21 portion. The provision of the function of a wiring pattern to the lead frame connector 20 facilitates configuring circuits through connections between the boards. The connections between the lead wires can be established not only with a lead frame, but with circuit components or by wire bonding as well.

In this embodiment, one end of each of the lead wires 21 is connected to the wiring pattern of the first main wiring board 11 with solder (not shown), while the other end is connected to the wiring pattern of the second main wiring board 12 with solder (not shown). As will be described later, a three-dimensional mounting structure 100 of this embodiment is produced by bending the lead wires 21 of the lead frame connector 20 such that the first main wiring board 11 and the second main wiring board 12 are substantially parallel to each other, so that each of the lead wires 21 is provided with a bent portion 21c in the configuration of this embodiment.

Typically, all of the plurality of lead wires 21 of the lead frame connector 20 are connected to the wiring pattern of the first main wiring board 11 or the second main wiring board 12. However, lead wires 21 that are not connected to the above-described wiring patterns also may be formed. In order to achieve a technical significance by using the lead frame connector 20 rather than other connection members, it is preferable that at least two of the plurality of lead wires 21 are connected to the wiring pattern of the first main wiring board 11 or the second main wiring board 12. The reason is that an electrical connection established by a lead frame connector 20 having only a single lead wire does not significantly differ from a simple electrical connection established by a single wiring (a single lead wire). The plurality of lead wires 21 are arranged substantially parallel to one another at an interval of, for example, at most 0.5 mm. In order to realize a narrower pitch, it is preferable that the interval is, for example, at most 0.3 mm. In this embodiment, the lead wires 21 are arranged with a pitch of, for example, 500 μm (lead wire width: 200 μm, lead wire interval: 300 μm). As will be described later, an anti-noise component such as a capacitor, an inductor and a varistor can be mounted on a portion between the lead wires 21 in the resin portion 22, depending on the situation.

Although the electronic components 30 are mounted on one side of the first or the second main wiring board 11 or 12 in the example shown in FIG. 2, the electronic components 30 can be mounted on both sides of the first or the second main wiring board 11 or 12 if these wiring boards are double-sided printed-circuit boards. Furthermore, as shown in FIG. 3, two or more lead frame connectors 20 (20A, 20B) may be used to connect the first main wiring board 11 and the second main wiring board 12 at two or more locations. Providing the connection at two or more locations makes it easier to maintain the three-dimensional structure formed by the first main wiring board 11 and the second main wiring board 12. In addition, the three-dimensional mounting structure 100 of this embodiment may be used as a module in the above-described form, or may be mounted on, for example, the board (mother board) 7 shown in FIG. 1. The three-dimensional mounting structure 100 also may be formed using only the lead frame connector 20B shown in FIG. 3.

When the three-dimensional mounting structure 100 of this embodiment is incorporated in a mobile phone, the first main wiring board 11 and the second main wiring board 12 can correspond to various circuit portions (e.g., a high-frequency circuit portion, a baseband portion, a power management portion, a display portion and an image sensor portion). Alternatively, the three-dimensional mounting structure 100 may correspond to a single circuit portion (e.g., a high-frequency circuit portion), and the first main wiring board 11 and the second main wiring board 12 may be elements constituting that circuit portion.

According to the configuration of this embodiment, the three-dimensional mounting structure 100 is formed by the first main wiring board 11, the second main wiring board 12 and the lead frame connector 20, so that the three-dimensional positional relationship between the first main wiring board 11 and the second main wiring board 12 makes it possible to realize high-density mounting. Moreover, it is possible to provide a separate function for each of the first main wiring board 11 and the second main wiring board 12, or to form each of the first main wiring board 11 and the second main wiring board 12 as an individual element of a given circuit, thereby performing multi-function mounting.

Furthermore, since the first main wiring board 11 and the second main wiring board 12 are electrically connected via the lead frame connector 20, each of the first main wiring board 11 and the second main wiring board 12 can be produced independently, and can be tested before being assembled into the three-dimensional mounting structure 100. Accordingly, it is possible to increase the reliability of the circuits implemented by the first and the second wiring boards 11 and 12, and to reduce the manufacturing cost. At the time of repair, the three-dimensional mounting structure 100 can be disassembled into various elements (the first main wiring board 11, the second main wiring board 12 and the lead frame connector 20) by removing the solder from the lead wires 21 of the lead frame connector 20, facilitating the repair. This structure is convenient not only in the manufacturing phase in a mass production, but also in producing a prototype module (three-dimensional mounting structure).

Furthermore, when improvements are required due to model changes and the like, for example, only the first main wiring board 11 of the circuits implemented by the first and the second main wiring boards 11 and 12 needs to be improved, and if no improvement is required for the second main wiring board 12, design modifications may be made only to the first main wiring board 11. Accordingly, it is possible to reduce the designing and development periods significantly, and to design and to manufacture the next models while maintaining the reliability of the second main wiring board 12.

Additionally, in the three-dimensional mounting structure 100 of this embodiment, it is possible to mount an electronic component on the lead frame connector 20. By mounting an electronic component on the lead frame connector 20, even higher-density mounting can be realized. Noise protection can be provided for the three-dimensional mounting structure 100 by using an anti-noise component (e.g., a capacitor, a varistor and an inductor) as the electronic component mounted on the lead frame connector 20. When the anti-noise component is mounted on the lead frame connector 20, it is possible to utilize the mounting area of the first or the second main wiring board 11 or 12 more effectively than when the anti-noise component is mounted on the first or the second main wiring board 11 or 12, while increasing the design flexibility of the first or the second main wiring board 11 or 12. In this specification, “anti-noise component” refers to components achieving a noise reduction. The anti-noise component can be selected from, for example, a by-pass capacitor, a decoupling capacitor, a delay inductor, a resistor and a varistor. Alternatively, it is possible to incorporate a semiconductor device or a chip component in the lead frame connector 20.

Although FIGS. 4A to 4C do not show a structure in which an electronic component is mounted in the lead frame connector 20, an example of this configuration can be given by mounting an electronic component with solder or the like such that the electronic component is electrically connected to at least two of the plurality of lead wires 21 shown in FIG. 4A, and forming the resin portion 22 so as to seal the whole or a portion of the electronic component.

The lead wires 21 of the lead frame connector 20 have higher flexibility than the first or the second main wiring board 11 or 12, thus providing a new effect on the configuration of the three-dimensional mounting structure 100 of this embodiment.

That is, the lead wires 21 of the lead frame connector 20 are more easily deformable elastically than the first main wiring board 11 and the second main wiring board 12, in other words, the lead frame connector 20 has a relatively high flexibility, so that stress or distortion exerted on the three-dimensional mounting structure 100 can be absorbed or alleviated by the lead wires 21 of the lead frame connector 20. This can improve the reliability against, for example, impact in the event of a fall. More specifically, although portable electronic devices and the like can be carried easily and therefore are convenient, they may be dropped accidentally. On such an occasion, a configuration simply formed by a usual board provided with a usual connector connection, for example, can suffer connection failure, resulting in circuit malfunction. On the other hand, according to the configuration of this embodiment, it is possible to avoid or to alleviate such a connection failure resulting from a fall, since stress or distortion exerted on the three-dimensional mounting structure 100 can be absorbed or alleviated by the lead frame connector 20. The flexibility of the lead frame connector differs depending on a material. For example, a Cu alloy or Fe alloy has about 120 GPa in Young's modulus. There is also known a material with a maximum Young's modulus of 220 GPa.

If the lead wires 21 of the lead frame connector 20 are too soft, then it may not be able to support the first and the second main wiring boards 11 and 12, or may not be able to absorb or to alleviate stress. Accordingly, it is preferable that the lead wires 21 of the lead frame connector 20 have a moderate flexibility. The lead wires 21 can be provided with a moderate amount of elastic deformation, in other words, the lead frame connector 20 can be provided with a relatively moderate flexibility, by appropriately selecting the material constituting the lead wires 21, the thickness and the number of the lead wires 21 and the like. In this embodiment, a rigid board is used for both of the first and the second main wiring boards 11 and 12, and the first and the second main wiring boards 11 and 12 are made of, for example, a typical glass epoxy in which nonwoven glass fabric is impregnated with an epoxy resin. In this case, the lead wires 21 of the lead frame connector 20 are deformable elastically to a greater extent, so that the lead frame connector 20 has a relatively high flexibility.

The interval D between the first main wiring board 11 and the second main wiring board 12 is, for example, at most 4.2 mm, and the smaller the interval, the smaller the thickness of the three-dimensional mounting structure 100 can be, unless a particular problem arises. From the viewpoint of performing high-density mounting, when a semiconductor chip is mounted as the electronic component 30a shown in FIG. 2, it is preferable to mount a CSP semiconductor chip or a bare chip. The three-dimensional mounting structure 100 can be placed as a thin module in the casing of a mobile phone or the like with a relative ease by setting the overall height H of the three-dimensional mounting structure 100 to, for example, at most 5 mm. In the case of mounting the three-dimensional mounting structure 100, the wiring board (mother board 7) on which it is placed may be a rigid board or a flexible board (or a flex-rigid board).

Exemplary dimensions of the first main wiring board 11 or the second main wiring board 12 are as follows. For example, in mobile phone applications, the area of the first main wiring board 11 (or the second main wiring board 12) may be, for example, at most 1500 mm² (e.g., dimensions of 30 mm×50 mm or smaller), and the thickness of the first main wiring board 11 (or the second main wiring board 12) may be, for example, at most 0.4 mm. The wiring pattern of the first main wiring board 11 (or the second main wiring board 12) may be made of, for example, copper foil. Exemplary dimensions of the lead frame connector 20 are as follows. The length of a single lead wire 21 can be defined by the interval D in the three-dimensional mounting structure 100, and may be, for example, from about 0.5 mm to about 2 mm in this embodiment. The thickness of the lead wires 21 (the diameter, if the lead wires 21 are circular) may be, for example, about 0.15 mm to about 0.3 mm. The area of the principal surface of the resin portion 22 of the lead frame connector 20 varies depending on the number of the lead wires 21, and may be, for example, at most 40 mm² (e.g., dimensions of 2 mm width×20 mm length or smaller), and the thickness of the resin portion 22, may be, for example, at most 1 mm. The bent portions 21c of the lead wires 21 may be bent substantially at a right angle, but they also may be bent so as to form a curve, instead of being bent at a right angle. It also is possible to process the lead wires 21 (e.g., providing recessed portions to facilitate bending of the lead wires 21) such that the bent portions 21c can be formed readily.

As the first main wiring board 11 and/or the second main wiring board 12, it also is possible to use a component-incorporating board that contains the electronic components in its substrate (see e.g. JP H11-220262A). The use of a component-incorporating board can facilitate high-density mounting of components. By using a component-incorporating board as the first main wiring board 11 and/or the second main wiring board 12, the area of the boards can be reduced by about 50%. Furthermore, the use of a component-incorporating board also provides the possibility of achieving the effect of reducing noise in the boards, for example, by the function of decreasing the connection distance. On the other hand, as described above, it also is possible to incorporate, for example, an anti-noise component in the resin portion 22 of the lead frame connector 20.

In the three-dimensional mounting structure 100 of this embodiment, the first main wiring board 11 and the second main wiring board 12 are disposed substantially parallel to each other, and the lead frame connector 20 is disposed substantially perpendicular to the first main wiring board 11 and/or the second main wiring board 12. However, the arrangement may deviate from a parallel or perpendicular (right angle) arrangement, as long as the configuration of the three-dimensional mounting structure 100 can be maintained relatively stably. Although the substantially parallel and the substantially perpendicular arrangements shown in, for example, FIG. 2, typically are parallel and perpendicular (at a right angle), respectively, there is no limitation to these arrangements. For example, the angle formed by the lead frame connector 20 and the first and the second main wiring boards 11 and 12 typically is about 90°, but also may be in the range of 70° to 110° (i.e., 90°±20°). The angle also may be outside this range, as long as the configuration of the three-dimensional mounting structure 100 can be maintained.

The configuration according to embodiments of the present invention is referred to as “three-dimensional mounting structure”. This term is described below. Since most electronic devices have a three-dimensional structure, electronic devices essentially are three-dimensional devices (i.e., three-dimensionally assembled devices, in a broad sense. This means that actual electronic devices have a three-dimensionally assembled configuration, or in other words, they are three-dimensionally mounted. However, in the electronic device mounting relating to the field of the present invention, a simple assembly of devices having a three-dimensional configuration is not called three-dimensional mounting. Therefore, such an assembly also is not referred to as three-dimensional mounting in this specification, but is referred to as “three-dimensional assembly” or “three-dimensional assembled body” to distinguish it from the three-dimensional mounting. In this specification, “three-dimensional assembled body” includes a three-dimensionally assembled configuration as seen in, for example, desk-top PCs (personal computers) in which daughter boards on which a printed circuit is mounted are inserted to socket connectors on a mother board and incorporated in a shelf-like arrangement. The scale of “three-dimensional assembled body” is, for example, as follows: Daughter boards with a size of about 100 mm×250 mm are inserted into connectors, and the distance between the daughter boards is about 25 mm. On the other hand, the scale of “three-dimensional mounting structure” is, for example, as follows: As described above, the size of the first and the second main wiring boards 11 and 12 is at most about 30 mm×50 mm, and the distance between the main wiring boards 11 and 12 is about 2 mm. Therefore, “three-dimensional assembly” and “three-dimensional mounting structure” differ from each other significantly.

Furthermore, in the case of the three-dimensional assembled body, connectors or flexible boards are used to electrically connect two boards. This, however, often results in an insufficient number of connection lines in the case of the three-dimensional mounting structure. In order to establish connection with a narrow pitch, for example, it is necessary to use connectors capable of establishing connection with a narrow pitch, or an increased number of layers of flexible boards. However, there is a limit to a narrow pitch achieved with connectors, and also to the number of layers of flexible boards. In such situations, the three-dimensional mounting structure 100 readily can be adapted for realizing a narrower pitch, thus achieving great technical significance. That is, this embodiment allows easier adjustment of the interval between the lead wires 21 than that can be achieved with connectors or flexible boards, and therefore is suitable for realizing a narrower pitch.

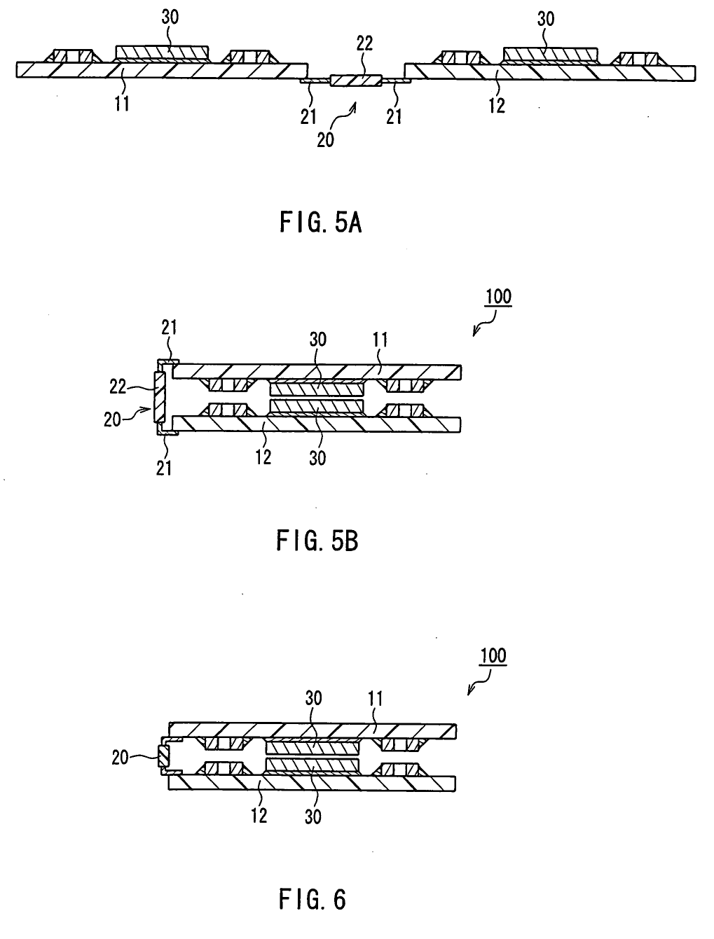

In the following, a method for producing a three-dimensional mounting structure 100 according to this embodiment is described with reference to FIGS. 4A to 4C, and FIGS. 5A and 5B.

FIGS. 4A to 4C are diagrams for illustrating the steps of a method for producing a lead frame connector 20.

First, a plurality of lead wires 21 are arranged as shown in FIG. 4A. Although only lead wires 21 arranged in parallel are shown in the example shown in FIG. 4A for the sake of clarity, it is convenient to prepare a lead frame including a configuration in which the lead wires 21 are arranged, and to carry out this step using that lead frame.

Next, a resin portion 22 is formed at a central area of the plurality of lead wires 21 by transfer molding, obtaining a lead frame connector 20 as shown in FIGS. 4B and 4C. FIGS. 4B and 4C, respectively, are a perspective view and a side view of the lead frame connector 20.

Next, as shown in FIG. 5A, one end and the other end of the lead wires 21 of the lead frame connector 20 are electrically connected, respectively, to a wiring pattern (not shown) of a first main wiring board 11 and a wiring pattern (not shown) of a second main wiring board 12, with the first main wiring board 11 and the second main wiring board 12 being placed side by side. Here, connection may be established with solder.

Next, as shown in FIG. 5B, the lead wires 21 of the lead frame connector 20 are bent such that the first main wiring board 11 and the second main wiring board 12 are disposed substantially parallel to each other, obtaining the three-dimensional mounting structure 100 according to this embodiment.

Although the lead wires 21 of the lead frame connector 20 are connected on the lower surface side of the first main wiring board 11 and the second main wiring board 12 in FIG. 5A, the lead wires 21 may be connected on the upper surface side. In this case, a three-dimensional mounting structure 100 having a configuration as shown in FIG. 6 can be obtained by bending the lead wires 21. This bending step can be carried out, for example, by bending the wiring boards 11 and 12, while fixing the soldered portion of the lead wires 21 with a fixing jig.

In order to stabilize the three-dimensional configuration of the three-dimensional mounting structure 100 more than those shown in FIGS. 5B and 6, a further lead frame connector 20 may be connected, for example, with solder, as shown in FIG. 3. In this case, it is convenient to use lead wires 21 having bent portions 21c.

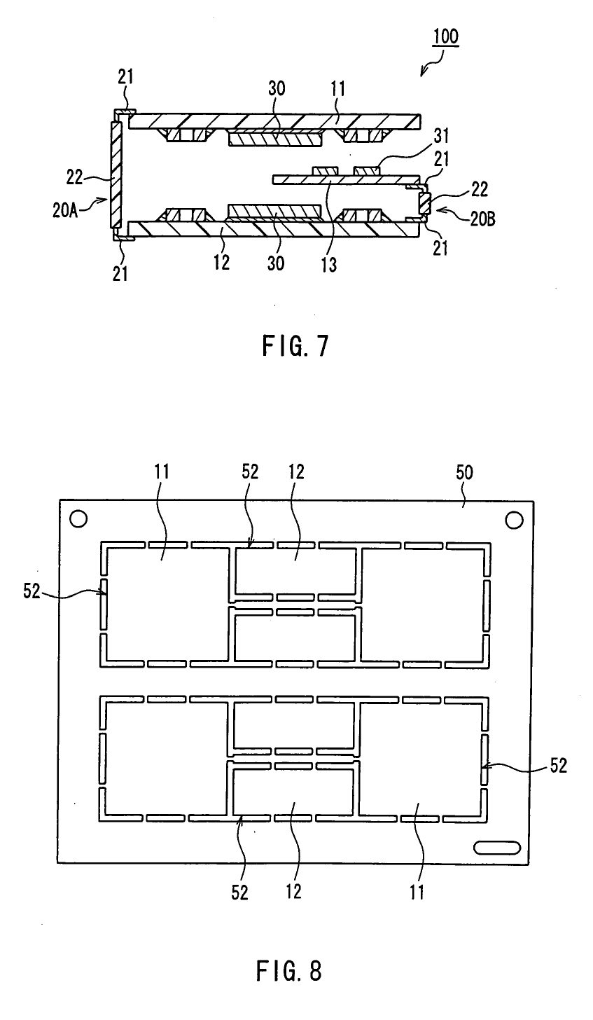

Further, as shown in FIG. 7, it also is possible to form a configuration in which main wiring boards (11, 12, 13) are disposed in three layers by the bending step. In the configuration shown in FIG. 7, the first main wiring board 11 and the second main wiring board 12 are connected with a lead frame connector 20A, and the second main wiring board 12 and the third main wiring board 13 are connected with a lead frame connector 20B. First, the lead wires of the lead frame connector 20B are bent such that the third main wiring board 13 is disposed inside facing the second main wiring board 12, and then the lead wires 21 of the lead frame connector 20A are bent such that the third main wiring board 13 is disposed between the first main wiring board 11 and the second main wiring board 12. In the example shown in FIG. 7, electronic components 31 are mounted on the third main wiring board 13.

In the following, another method for producing a three-dimensional mounting structure 100 is described with reference to FIGS. 8 to 11.

First, as shown in FIG. 8, a multi-board substrate 50 including first main wiring boards 11 and second main wiring boards 12 is prepared. The multi-board substrate 50 includes a plurality of combinations in each of which the first main wiring board 11 and the second main wiring board 12 are disposed adjacent to each other, and includes four such combinations in the example shown in FIG. 8. Each of these four combinations is subjected to the steps of the production method of this embodiment, and formed into the three-dimensional mounting structure 100.

Division lines 52 are formed on the periphery of the first main wiring boards 11 and the second main wiring boards 12 of the multi-board substrate 50. In this embodiment, the division lines 52 are perforations. It also is possible to make V-shaped cuts as the division lines 52.

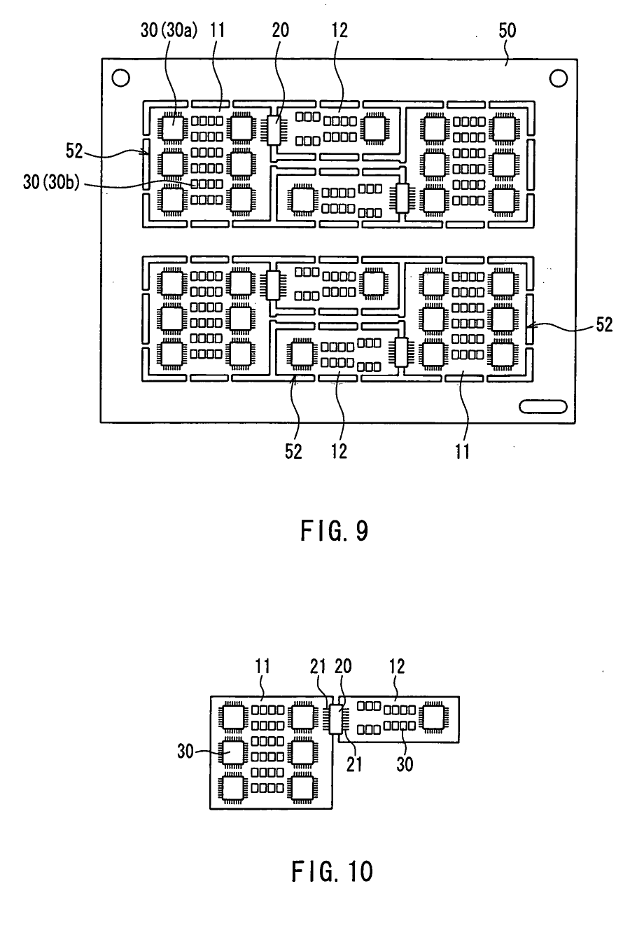

Next, as shown in FIG. 9, electronic components 30 (30a, 30b) are mounted on wiring patterns (not shown) of the first main wiring boards 11 and the second main wiring boards 12. Then, lead frame connectors 20 for connecting the first main wiring boards 11 and the second main wiring boards 12 also are mounted. It is possible to mount the electronic components 30 and the lead frame connectors 20 in the same step, or it is possible to use a multi-board substrate 50 on which the electronic components 30 have been mounted in advance, and to mount the lead frame connectors 20 on that multi-board substrate 50. By cutting this multi-board substrate 50 along the division lines 52, a total of four sets of boards are produced.

Next, FIG. 10 shows a single combination unit of the first main wiring board 11 and the second main wiring board 12 connected via the lead frame connector 20, cut out along the division lines (perforations) 52 shown in FIG. 9 as described above. It should be noted that even when no division line 52 is formed on the multi-board substrate 50, the above-described combination can be removed, for example, by punching or cutting.

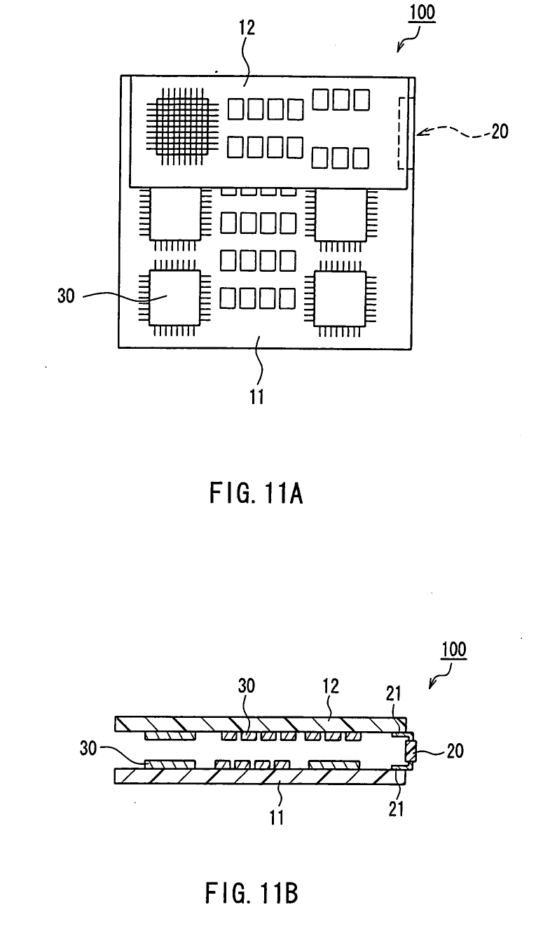

Thereafter, as shown in FIGS. 11A and 11B, the lead wires 21 of the lead frame connector 20 are bent, thus obtaining a three-dimensional mounting structure 100 of this embodiment. According to this production method, a large number of the three-dimensional mounting structures 100 can be produced with high efficiency.

According to the production method of this embodiment, the three-dimensional mounting structure 100 can be produced by bending the lead wires 21 of the lead frame connector 20 such that the first main wiring board 11 and the second main wiring board 12 are disposed substantially parallel to each other, so that it is possible to produce the three-dimensional mounting structure relatively easily, as compared with the production method of conventional three-dimensional mounting structures (or the three-dimensional mounting structures 10 shown in FIGS. 1A and 1B). Furthermore, the use of the multi-board substrate 50 makes it possible to produce a large number of the three-dimensional mounting structures 100 easily.

One of the techniques of bending boards is a technique using a flex-rigid board. However, the manufacturing steps of the flex-rigid board are complicated, and tend to increase the cost. Moreover, the production method of the flex-rigid board is very wasteful, because a large area of the flexible board portion of the flex-rigid board is discarded from the final product. In contrast, the production method of this embodiment can produce a low-cost three-dimensional mounting structure 100, and also achieves the bendability obtained by flex-rigid boards, with the lead frame connector 20. Furthermore, since no particular portion will be discarded over a large area, it is very effective.

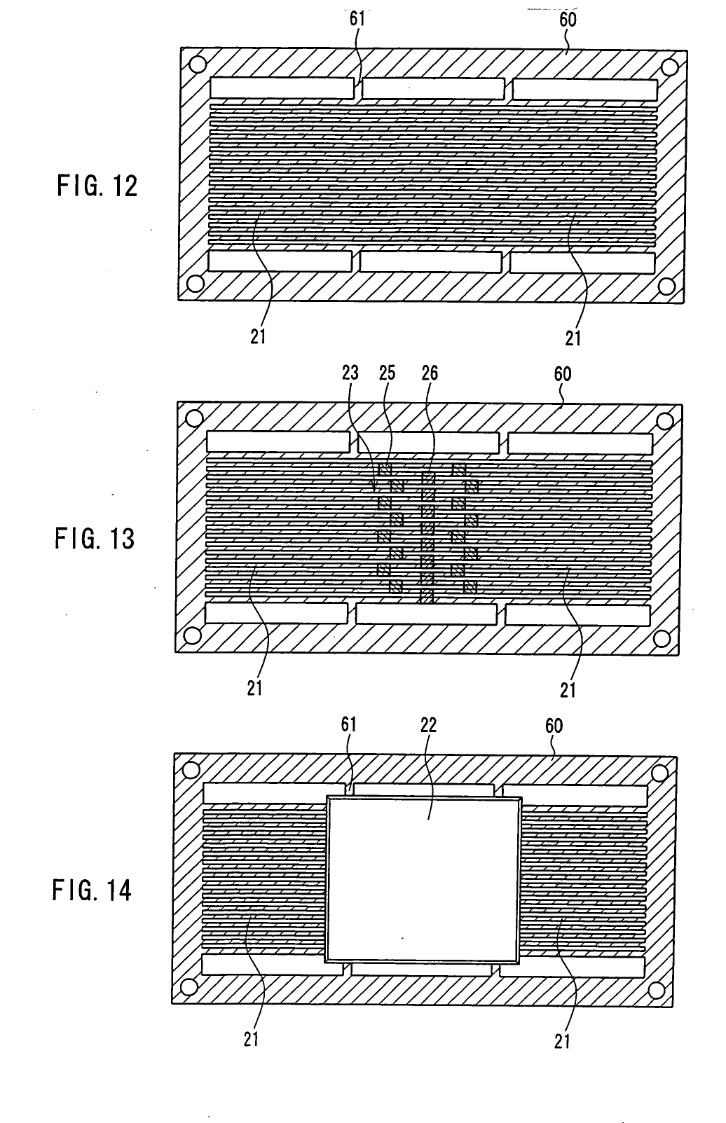

In the following, a method for producing a component-incorporating lead frame connector 20 is described with reference to FIGS. 12 to 15.

First, as shown in FIG. 12, a lead frame 60 including a plurality of lead wires 21 is prepared. The lead wires 21 are arranged at the same intervals, and one end and the other end of the lead wires 21 are connected to the lead frame 60. In the example shown in FIG. 12, the lead frame 60 is provided also with lead-hanging portions 61.

Next, as shown in FIG. 13, electronic components 25 or 26 are placed on a portion of a central area 23 of the lead wires 21. The central area 23 of the lead wires 21 is an area in which a resin portion 22 is formed. The electronic components 25 and 26 are, for example, anti-noise components, and the electronic components 25 and 26 are mounted so as to extend across gaps between the lead wires 21, in the example shown in FIG. 13.

Next, as shown in FIG. 14, the center of the lead frame 60 (i.e., the central area 23 of the lead wires 21) is sealed with resin by transfer molding, thereby forming a resin portion 22 containing the electronic components 25.

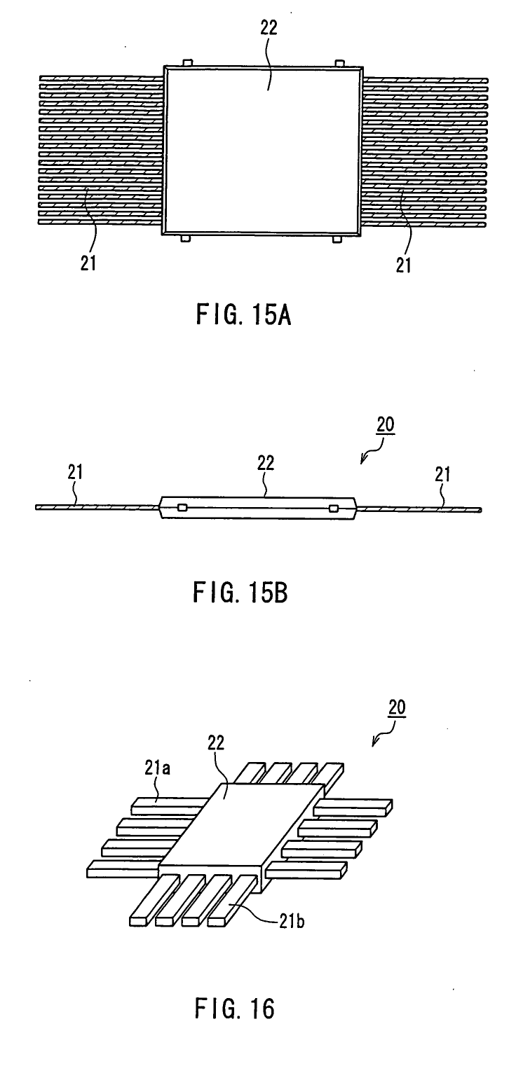

Finally, the lead frame connector 20 incorporating the electronic components 25 and 26 is removed from the lead frame 60, thus obtaining a lead frame connector 20 as shown in FIGS. 15A and 15B. FIGS. 15A and 15B, respectively, are a top view and a side view of the component-incorporating lead frame connector 20.

Also in the case of using this component-incorporating lead frame connector 20, it is possible to carry out the steps shown in FIGS. 5A and 5B and the steps shown in FIGS. 8 to 11. Accordingly, it is understood that even higher-density mounting can be realized by incorporating electronic components in the lead frame connector 20. The use of anti-noise components as the electronic components 30 mounted on the lead frame connector 20 makes it possible to provide noise protection with the lead frame connector 20, and therefore is very advantageous.

### Embodiment 2

In the following, a three-dimensional mounting structure according to Embodiment 2 of the present invention is described with reference to FIGS. 16 to 21. The three-dimensional mounting structure of this embodiment is an improvement or a modification of the configuration of Embodiment 1 described above. For the sake of simplicity, the description of aspects similar to those of the configuration of Embodiment 1 described above has been omitted.

FIG. 16 is a perspective view of a lead frame connector 20 whose lead wires (21a, 21b) extend in two directions. In the case of the lead frame connector 20 shown in FIG. 16, lead wires 21a that constitute a portion of the plurality of lead wires 21 extend in a substantially parallel arrangement in a first direction, and lead wires 21b that constitute the remaining portion extend in a substantially parallel arrangement in a second direction that is different from the first direction. In this embodiment, the lead wires 21a and the lead wires 21b intersect at a substantially right angle. This lead frame connector 20 also can be produced easily by arranging the lead wires 21 extending in two directions, and thereafter performing transfer molding. It should be noted that the lead wires 21a and the lead wires 21b partially may be electrically connected to one another, or none of these lead wires may be electrically connected.

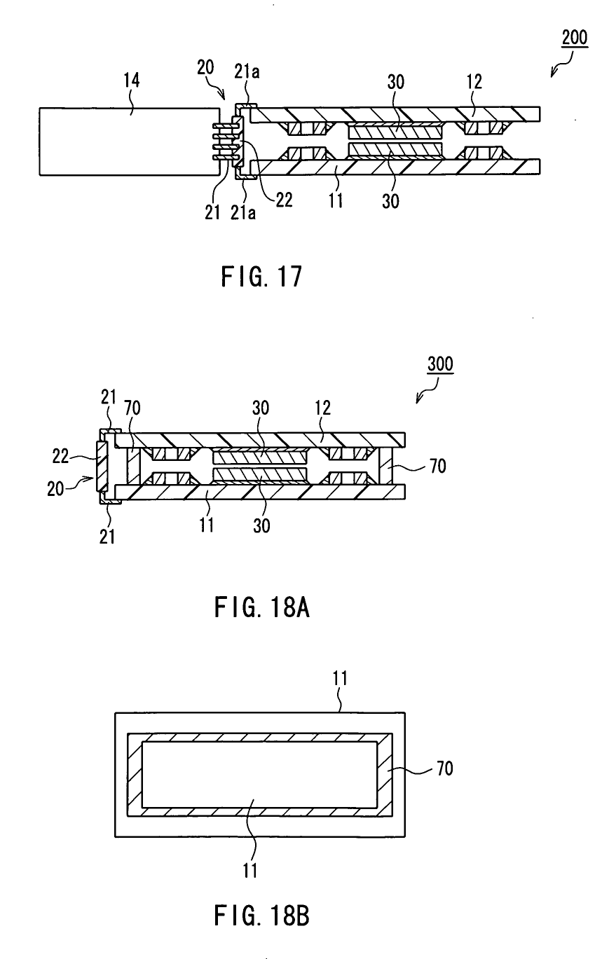

FIG. 17 shows an example of a three-dimensional mounting structure 200 using the lead frame connector 20 shown in FIG. 16. In the case of the three-dimensional mounting structure 200 shown in FIG. 17, the lead wires 21a connect the first main wiring board 11 and the second main wiring board 12. Then, the lead wires 21b are connected to another main wiring board 14 that is different from the first and the second main wiring boards 11 and 12. Thus, the use of the lead frame connector 20 shown in FIG. 16 makes it possible to realize a variety of three-dimensional configurations.

In the following, reference is made to FIGS. 18A and 18B, which schematically show the configuration of a three-dimensional mounting structure 300 in which a shield wall 70 for shielding electromagnetic waves is formed between the first main wiring board 11 and the second main wiring board 12. FIG. 18A is a cross-sectional view of the three-dimensional mounting structure 300, and FIG. 18B is a top view of the three-dimensional mounting structure 300, taken from above the first main wiring board 11 (between the first main wiring board 11 and the second main wiring board 12). It should be noted that the electronic components 30 have been omitted in FIG. 18B. The shield wall 70 is formed around the inner side of the first main wiring board 11, so that it is possible to shield electromagnetic waves from outside, and to shield those from the inside.

Since the shield wall 70 provided in the three-dimensional mounting structure 300 is capable of shielding electromagnetic waves, it is possible to provide noise protection with the shield wall 70. The shield wall 70 is made of an anti-electromagnetic wave material, including for example, metal (e.g., Cu or Al), a magnetic material (e.g., ferrite), or resin in which metal or a magnetic material is dispersed. In this embodiment, a shield member (also referred to as “reflow shield”) made of a solderable magnetic material is used as the shield wall 70. The shield member made of a solderable magnetic material is, for example, a machined (e.g., machined as shown in FIG. 18B) nickel plate, which is a magnetic material, and it is possible to place solder on a portion of the nickel plate. This makes it possible to carry out positioning in the three-dimensional mounting structure, as well as performing electrical and mechanical fixing.

As shown in FIG. 18B, the shield wall 70 is disposed on the periphery (an edge portion) of the first main wiring board 11 (or the second main wiring board 12), and a substantially closed space is formed by the first and the second main wiring boards 11 and 12 and the shield wall 70. This substantially closed space is shielded, and therefore is suitable for placing a semiconductor chip (e.g., a system LSI or a high-frequency LSI for controlling the logic or the sound source of a mobile phone).

Although the shield wall 70 is used in FIG. 18, noise protection can be provided by disposing not only the shield wall 70, but also a shield member for shielding electromagnetic waves between the first main wiring board 11 and the second main wiring board 12. Examples of such a shield member include a sheet material made of a silicone resin in which powder of a magnetic material and/or powder of an electromagnetic wave absorber is dispersed.

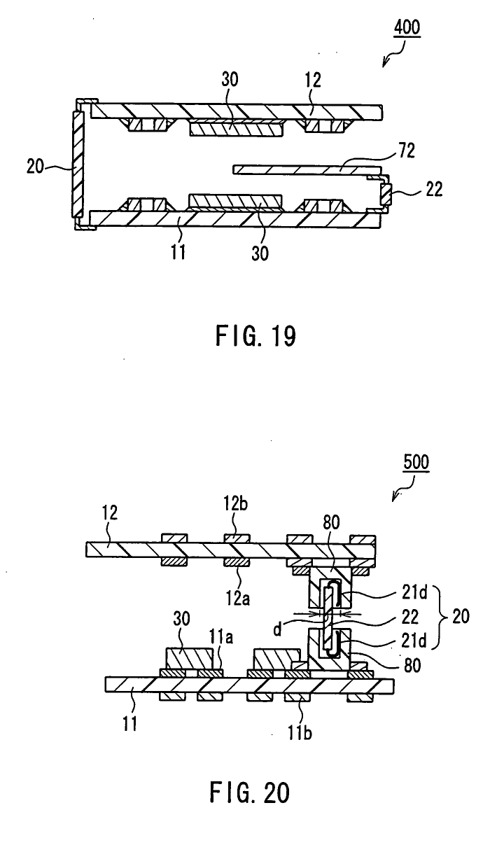

FIG. 19 shows an exemplary configuration in which a shield member 72 is disposed between the first main wiring board 11 and the second main wiring board 12. The configuration of a three-dimensional mounting structure 400 shown in FIG. 19 is maintained by connecting the shield member 72 and the second main wiring board 12 with the lead frame connector 20. With the shield member 72, it is possible to shield electromagnetic waves between the first main wiring board 11 and the second main wiring board 12.

Although the lead wires 21 of the lead frame connector 20 and the main wiring board 11 or 12 are connected, for example, with solder in the above-described embodiment, it is possible to employ any other method other than using solder. For example, it is possible to use connectors 80, as shown in FIG. 20.

A three-dimensional mounting structure 500 shown in FIG. 20 includes: a connector 80 electrically connected to a wiring pattern 11a of the first main wiring board 11; and a connector 80 electrically connected to a wiring pattern 12a of the second main wiring board 12. In the configuration shown in FIG. 20, the lead wires 21 of the lead frame connector 20 have curved areas 21d, and each of the connectors 80 is capable of housing the curved areas 21d of the lead wires 21. The connectors 80 shown in FIG. 20 have a configuration in which the curved areas 21d of the lead wires 21 can be housed and removed.

The provision of the connectors 80 makes it possible to ensure the repairability of the three-dimensional mounting structure 500. That is, since the use of the connectors 80 facilitates connection and removal of the lead frame connector 20 as compared with solder bonding, it is possible to carry out a repair after testing the electrical connections between the lead frame connector 20 and, for example, the first main wiring board 11, if the test result indicates a failure. Accordingly, it is possible to improve the manufacturing yield. Furthermore, by utilizing this repaired structure to produce a prototype for designing and development, it also is possible to increase the pace of designing and development. It is needless to say that it also is possible to use both the connectors 80 and solder in combination. From the viewpoint of the scale of the three-dimensional mounting structure 500, it is preferable to use dedicated connectors as the connectors 80 shown in FIG. 20.

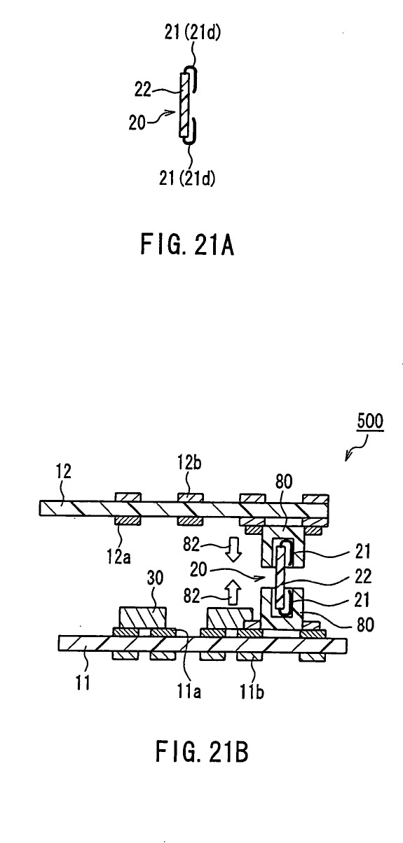

FIG. 21A shows the lead frame connector 20 shown in FIG. 20. As shown in FIG. 21B, the curved areas 21d of the lead wires 21 of the lead frame connector 20 can be inserted and fitted into the connectors 80 by disposing the lead frame connector 20 between the connectors 80, and thereafter pressing the wiring boards 11 and 12 in the directions indicated by arrows 82. Consequently, the three-dimensional mounting structure 500 can be obtained. In the case of the three-dimensional mounting structure 500 shown in FIGS. 20 and 21B, the wiring patterns 11b and 12b are provided also on the back side of the first main wiring board 11 and the second main wiring board 12, respectively, so that is also is possible to use these wiring patterns 11b and 12b. As described above, since the connectors 80 are provided for the first main wiring board 11, the second main wiring board 12 or the lead frame connector 20, they have relatively small dimensions. For example, the internal space “d” shown in FIG. 20 is at most 500 μm (or about 100 μm to about 300 μm).

The three-dimensional mounting structures 100, 200, 300, 400 and 500 according to embodiments of the present invention can be housed in the casing of a portable electronic device, and can constitute the portable electronic device together with other components of the portable electronic device. Among portable electronic devices, the three-dimensional mounting structures of embodiments of the present invention are suitable particularly for mobile phones, for which there is a strict limitation on the mounting area. However, they can be used suitably for other portable electronic devices (e.g., PDAs). According to the present invention, it is possible to provide a three-dimensional mounting structure that can realize high-density, multi-function mounting, and a production method that readily can produce such a three-dimensional mounting structure.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

1. A three-dimensional mounting structure comprising:
a first main wiring board having a first wiring pattern on its surface and an electronic component mounted on the wiring pattern;
a second main wiring board disposed facing the first main wiring board and having a second wiring pattern on its surface; and
a lead frame connector disposed substantially perpendicular to the first main wiring board and the second main wiring board at an end portion of the two wiring bards,
wherein the lead frame connector comprises a plurality of lead wires made of an electrically conductive material and a resin portion to which the plurality of lead wires are fixed,
wherein an end portion of each of the plurality of lead wires is exposed from the resin portion, and
wherein at least two of the plurality of lead wires are each electrically connected to both the first wiring pattern of the first main wiring board and the second wiring pattern of the second main wiring board.

2. The three-dimensional mounting structure according to claim 1,
wherein the at least two lead wires each have a bent portion.

3. The three-dimensional mounting structure according to claim 1,
wherein the electronic components mounted on the first main wiring board and the second main wiring board are disposed on an inner side of each of the two wiring boards.

4. The three-dimensional mounting structure according to claim 1,
wherein the resin portion of the lead frame connector contains a further electronic component.

5. The three-dimensional mounting structure according to claim 4,
wherein the further electronic component is an anti-noise component.

6. The three-dimensional mounting structure according to claim 5,
wherein the anti-noise component is at least one selected from a by-pass capacitor, a decoupling capacitor, a delay inductor, a resistor and a varistor.

7. The three-dimensional mounting structure according to claim 1,
wherein the electronic component is at least one selected from a semiconductor device and a chip component.

8. The three-dimensional mounting structure according to claim 1,
wherein one end of each of the at least two lead wires is connected to the wiring pattern of the first main wiring board with solder, and the other end of each of the at least two lead wires is connected to the wiring pattern of the second main wiring board with solder.

9. The three-dimensional mounting structure according to claim 1, further comprising
a side board that is folded to a lateral side of at least one of the first main wiring board and the second main wiring board,
wherein the lead frame connector further comprises a plurality of side lead wires disposed in a direction perpendicular to the plurality of lead wires connected to each of wiring of the first main wiring board and the second main wiring board, and
wherein the side lead wires are electrically connected to wiring of the side board.

10. The three-dimensional mounting structure according to claim 1, further comprising:
a third wiring board or an electromagnetic wave-shielding member that is folded; and
a further lead frame connector comprising a plurality of lead wires made of an electrically conductive material and a resin portion to which the plurality of lead wires are fixed,
wherein the third wiring board or the electromagnetic wave-shielding member is connected, via the further lead frame connector, to an end of at least one of the first main wiring board and the second main wiring board that is opposite of an end at which the two wiring boards are connected.

11. The three-dimensional mounting structure according to claim 10,
wherein a substantially closed space is formed by the first main wiring board, the second main wiring board and the electromagnetic wave-shielding member.

12. The three-dimensional mounting structure according to claim 1,
wherein at least one of the first main wiring board and the second main wiring board is an electronic component-incorporating board that contains an electronic component in its substrate.

13. A method for producing a three-dimensional mounting structure, comprising:
arranging, side by side, a first main wiring board having a wiring pattern on its surface and an electronic component mounted on the wiring pattern, and a second main wiring board having a wiring pattern on its surface;
electrically connecting, to the wiring pattern of the first main wiring board, one end of each of a plurality of lead wires of a lead frame connector comprising the plurality of lead wires and a resin portion to which the lead wires are fixed, and electrically connecting the other end of each of the lead wires to the wiring pattern of the second main wiring board; and
bending the lead wires of the lead frame connector in such a manner that the first main wiring board and the second main wiring board face each other.

14. The method for producing a three-dimensional mounting structure according to claim 13,
wherein the lead frame connector is formed by arranging a plurality of lead wires and thereafter forming a resin portion at a central area of the plurality of lead wires by transfer molding.

15. The method for producing a three-dimensional mounting structure according to claim 14,
wherein the plurality of lead wires are arranged in a lead frame including the lead wires, and
an electronic component is placed on a portion of the central area of the plurality of lead wires, the electronic component being sealed in the resin by the transfer molding.

16. A method for producing a three-dimensional mounting structure, comprising:
providing a multi-board substrate including a plurality of combinations of a first main wiring board having a wiring pattern on its surface and a second main wiring board disposed adjacent to the first main wiring board and having a wiring pattern on its surface;
mounting an electronic component on each of the wiring pattern of the first main wiring board and the wiring pattern of the second main wiring board in the multi-board substrate;
electrically connecting one end and the other end of each of a plurality of lead wires of a lead frame connector comprising the plurality of lead wires and a resin portion to which the lead wires are fixed, respectively, to the wiring pattern of the first main wiring board and the wiring pattern of the second main wiring board in the combinations included in the multi-board substrate;
removing, from the multi-board substrate, the combinations of the first main wiring board and the second main wiring board connected via the lead frame connector; and
bending the lead wires of the lead frame connector in such a manner that the first main wiring board and the second main wiring board face each other.

17. The method for producing a three-dimensional mounting structure according to claim 16,
wherein at least one of a perforation and a V-shaped cut is formed on a periphery of the first main wiring board and the second main wiring board in the multi-board substrate.

18. The method for producing a three-dimensional mounting structure according to claim 16,
wherein the step of mounting an electronic component on each of the first main wiring board and the second main wiring board and the step of electrically connecting one end and the other end of each of the lead wires of the lead frame connector, respectively, to the wiring pattern of the first main wiring board and the wiring pattern of the second main wiring board are performed in the same step.

19. The method for producing a three-dimensional mounting structure according to claim 16,
wherein the lead frame connector is formed by arranging a plurality of lead wires and thereafter forming a resin portion at a central area of the plurality of lead wires by transfer molding.

20. The method for producing a three-dimensional mounting structure according to claim 19,
wherein the plurality of lead wires are arranged in a lead frame including the plurality of lead wires, and
wherein an electronic component is placed on a portion of a central area of the plurality of lead wires, the electronic component being sealed in the resin by the transfer molding.
